(19) United States
(12) Patent Application Publication
(10) Pub. No.: US 2024/0377749 A1
(43) Pub. Date: Nov. 14, 2024

(54) ASSISTED FEATURE PLACEMENT IN SEMICONDUCTOR PATTERNING

(71) Applicant: Geminatio, Inc., Schenectady, NY (US)

(72) Inventors: Brennan Peterson, Longmont, CO (US); Phillip D. Hustad, Longmont, CO (US)

(73) Assignee: Geminatio, Inc., Schenectady, NY (US)

(21) Appl. No.: 18/686,814

(22) PCT Filed: Aug. 25, 2022
(86) PCT No.: PCT/US2022/041554

§ 371 Date: Feb. 26, 2024

Related U.S. Application Data
(60) Provisional application No. 63/236,826, filed on Aug. 25, 2021.

(51) Int. Cl. G03F 7/16; H01L 21/027

(52) U.S. Cl. CPC G03F 7/16; H01L 21/0273

(57) ABSTRACT

A method of microfabrication includes providing a substrate having an existing pattern, wherein the existing pattern includes features formed within a base layer such that a top surface of the substrate has features uncovered and the base layer is uncovered, depositing a selective attachment agent on the substrate, wherein the selective attachment agent comprises a solubility-shifting agent, depositing a first resist on the substrate, activating the solubility shifting agent such that a portion of the first resist becomes insoluble to a first developer, and developing the first resist using the first developer such that the portion of the first resist insoluble to the first developer remains.

### BACKGROUND

Microfabrication of semiconductor devices includes various steps such as film deposition, pattern formation, and pattern transfer. Materials and films are deposited on a substrate by spin coating, vapor deposition, and other deposition processes. Pattern formation is typically performed by exposing a photo-sensitive film, known as a photoresist, to a pattern of actinic radiation and subsequently developing the photoresist to form a relief pattern. The relief pattern then acts as an etch mask, which, when one or more etching processes are applied to the substrate, cover portions of the substrate that are not to be etched. Accordingly, patterns that make up a functional device (such as transistors and diodes) are formed on a substrate, and which is then further treated.

Semiconductor patterning includes routine processing flows. A substrate layer is received with some pattern. This pattern is smoothed, and transfer layers are placed to improve the pattern shape. Next, photoresist and associated layers are deposited on the surface. Photoresist layers are exposed to a pattern via lithography, thereby creating a latent pattern. The latent pattern is then developed, forming a relief pattern that is resistant to etchants to be used as an etch mask. Finally, this relief pattern is etched into the transfer layers, then into the final substrate.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method of microfabrication including providing a substrate having an existing pattern, wherein the existing pattern includes features formed within a base layer such that a top surface of the substrate has features uncovered and the base layer is uncovered, depositing a selective attachment agent on the substrate, wherein the selective attachment agent comprises a solubility-shifting agent, depositing a first resist on the substrate, activating the solubility shifting agent such that a portion of the first resist becomes insoluble to a first developer, and developing the first resist using the first developer such that the portion of the first resist insoluble to the first developer remains.

In another aspect, embodiments of the present disclosure relate to a method of microfabrication including providing a substrate having an existing pattern, wherein the existing pattern comprises features formed within a base layer such that a top surface of the substrate has features uncovered and the base layer is uncovered, depositing a selective attachment agent on the substrate, wherein the selective attachment agent comprises a solubility-shifting agent, depositing a first resist on the substrate, activating the solubility shifting agent such that a portion of the first resist becomes soluble to a first developer, and developing the first resist using the first developer such that the portion of the first resist soluble to the first developer are removed.

Other aspects and advantages of the claimed subject matter will be apparent from the following description and the appended claims.

### BRIEF DESCRIPTION OF DRAWINGS

FIG. 1A is a schematic depiction of a selective self-aligned pattern on a substrate in accordance with one or more embodiment of the present disclosure.

FIG. 1B is a schematic depiction of an anti-selective self-aligned pattern on a substrate in accordance with one or more embodiment of the present disclosure.

FIG. 2 is a block-flow diagram of a method in accordance with one or more embodiments of the present disclosure.

FIGS. 3A-E are schematic illustrations of coated substrates at respective points of a method in accordance with one or more embodiments of the present disclosure.

FIG. 4 is a block-flow diagram of a method in accordance with one or more embodiments of the present disclosure.

FIGS. 5A-D are schematic illustrations of coated substrates at respective points of a method in accordance with one or more embodiments of the present disclosure.

### DETAILED DESCRIPTION

A challenge in substrate patterning is placing a designed pattern accurately with respect to underlying features, thus accurately shaping the final pattern. Another challenge is precisely sizing the final pattern as designed. Small variances in the size and shape can cause both short-term and long-term device failure.

As will be appreciated by one of ordinary skill in the art, films and materials that are added to, and removed from, a given substrate may subject the substrate to internal compressive and tensile stresses based on the materials and structure of shapes formed thereon. These internal stresses can warp and bow the substrate. Moreover, printing patterns at or below a resolution of a given photolithography tool often means more potential for pattern misplacement. Thus, a significant challenge is that a placed (exposed) pattern can be offset from a preceding pattern. This “registration” error or “overlay” error is one of the most significant challenges in device micro-fabrication. This challenge applies to layers on top of each other as well as layers next to each other.

Accordingly, improvement of pattern placement on a given subsequent layer is highly desired. Conventional pattern placement attempts to improve the pattern placement in lithography systems tend to include using highly accurate measurements and complex feedback loops.

The present disclosure generally relates to a method of pattern placement on a semiconductor substrate. Herein, the terms “semiconductor substrate” and “substrate” are used interchangeably, and may be any semiconductor material including, but not limited to, semiconductor wafers, semiconductor material layers, and combinations thereof. The method disclosed herein provides pattern placement and overlay that is locally and directly improved by inducing the pattern to form in the correct place (e.g., a target position or target region). In order to achieve a self-aligned pattern placement, the method may include either directing where the pattern is formed or inhibiting formation of patterns in non-desired places. In one or more embodiments, the method includes depositing or forming an assisting layer on a target position.

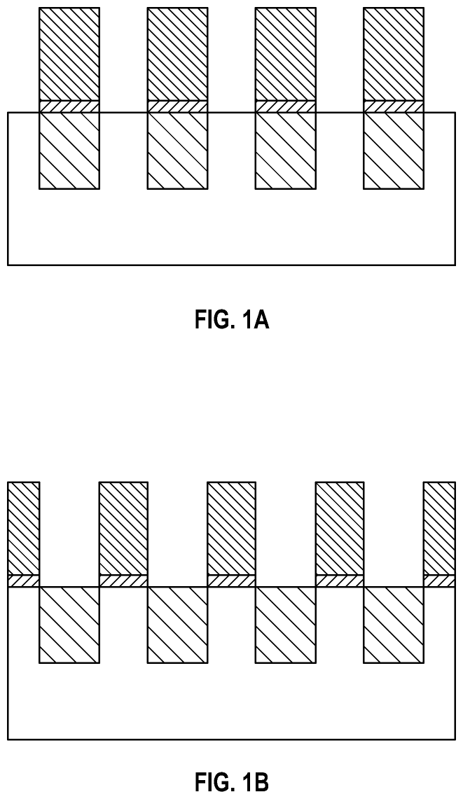

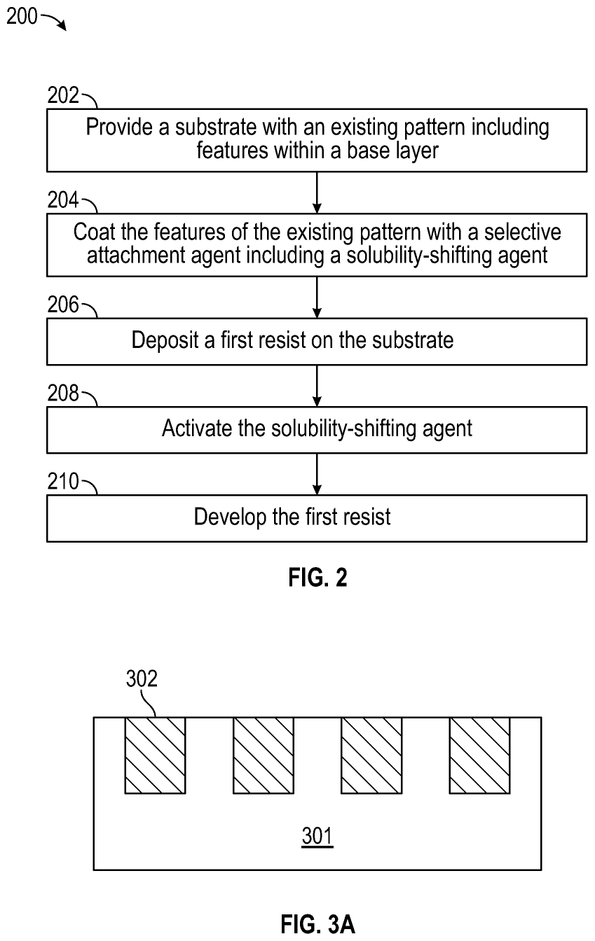

Methods in accordance with the present disclosure may include providing a substrate with an existing pattern, and then selectively forming a pattern of material either on top of, or alternate to, the existing pattern. A pattern of material selectively formed on top of the existing pattern according to one or more embodiments is shown in FIG. 1A. A pattern of material selectively formed alternate to, or offset from, the existing pattern included on the substrate according to one or more embodiments is shown in FIG. 1B.

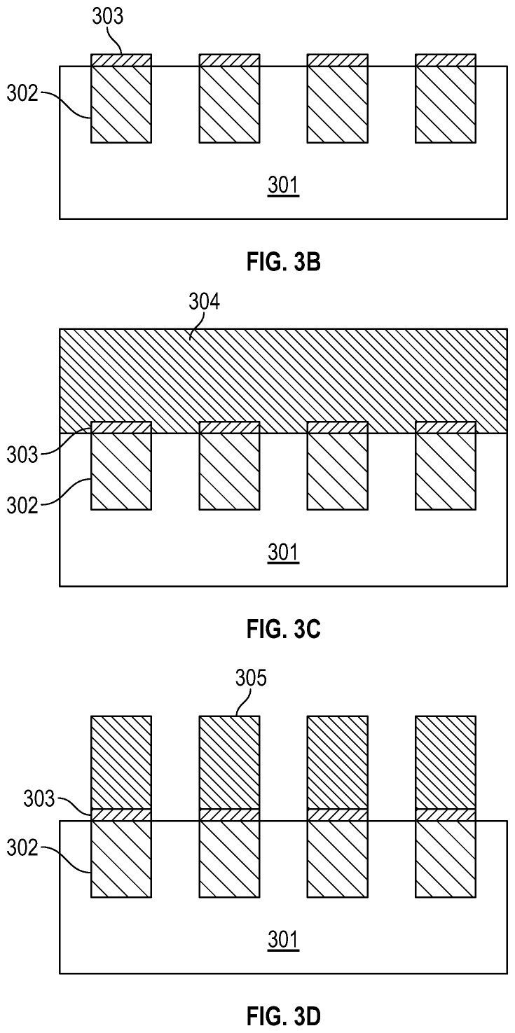

A method, 200, for selective pattern self-alignment (e.g., the pattern shown in FIG. 1A) in accordance with the present disclosure is shown in, and discussed with reference to, FIG. 2. Initially, an existing pattern is provided on a substrate at block 202. At block 204, the substrate, or a portion thereof, is coated with a selective attachment agent. The selective attachment agent may covalently bond with the surface. The selective attachment agent coating may optionally be pretreated. The optional pre-treatment may be a thermal treatment. The thermal treatment may facilitate a condensation reaction of the selective attachment agent with the surface. Then, at block 206, the substrate is coated with a first resist. A solubility-shifting agent may be provided on the first resist and then, as shown at block 208, the solubility-shifting agent may be activated to provide a region of the first resist that is soluble in a first developer. Finally, the first resist is developed at block 210 to provide a selective pattern of the first resist.

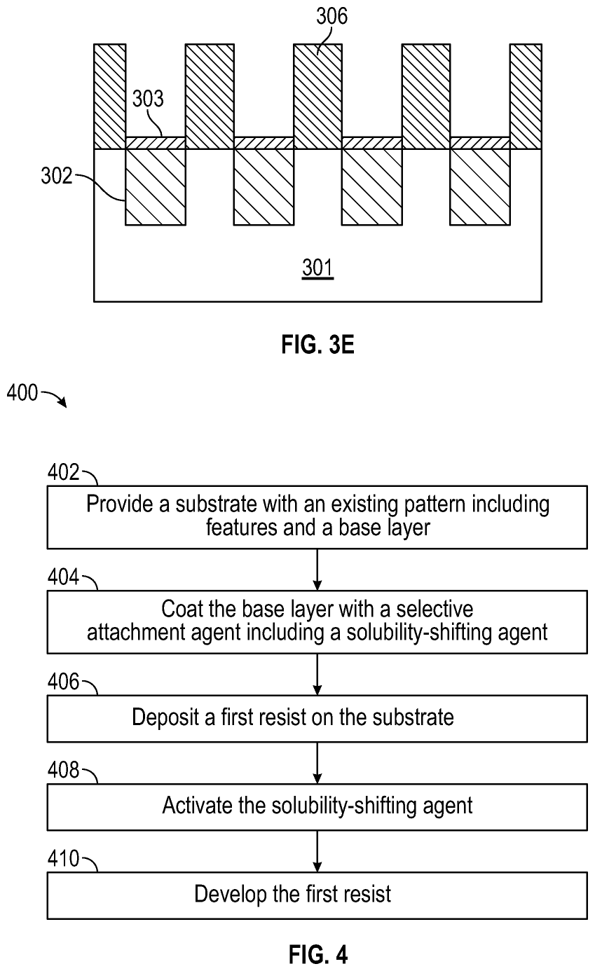

Schematic depictions of a coated substrate at various points during the method described above are shown in FIGS. 3A-3E. Herein “a coated substrate” refers to a substrate that is coated with one or more layers, such as a first resist layer and a second resist layer. FIG. 3A shows a substrate including an existing pattern. FIG. 3B shows a substrate including an overcoat including a selective attachment agent. FIG. 3C shows a substrate including a selective attachment agent overcoat layered with a first resist. Finally, FIG. 3D shows a coated substrate after the first resist has been developed, such that portions of the substrate are exposed. The method of FIG. 2 and coated substrates shown in FIGS. 3A-D are discussed in detail below.

In FIG. 2, at block 202, an existing pattern is provided on a substrate. FIG. 3A shows a substrate including an existing pattern. In FIG. 3A, the existing pattern includes features 302 formed in a base layer 301. The base layer may be any suitable substrate known in the art. In one or more embodiments, the features include a metal or other conductive structures. As used herein, the term metal includes alloys, stacks, and other combinations of multiple metals. For example, the metal interconnect lines may include barrier layers, stacks of different metals or alloys, etc. Suitable metals that may be present in the features include, but are not limited to, copper, cobalt, and tungsten. In one or more embodiments, the base layer is an interlayer dielectric. A suitable interlayer dielectric may include oxides of silicon (e.g., silicon dioxide (SiO₂)), doped oxides of silicon, fluorinated oxides of silicon, carbon doped oxides of silicon, various low-k dielectric materials known in the arts, and combinations thereof. The existing pattern may be a final feature or an intermediate feature in the patterning process. In some embodiments, the substrate is planarized such that the existing pattern is uncovered and accessible.

Then, at block 204, a selective attachment agent is coated on the substrate, or a portion thereof. The selective attachment agent may be coated over the substrate by any coating method known in the art. Suitable coating methods include, but are not limited to, vapor phase deposition, spin-on coating, and Langmuir-Blodgett monolayer coating. In one or more embodiments, the selective attachment agent is coated on a target region. Herein a “target region” or “target position” refers to a region on a substrate that is to receive a pattern.

The selective attachment agent may preferentially adhere to one material of the existing pattern. In one or more embodiments, the selective attachment agent adheres to the features of the existing pattern. FIG. 3B shows a substrate coated with a selective attachment agent 303 that is adhered to the features of the existing pattern. The selective attachment agent may adhere to the features of the pattern in a ratio great than 1:1. By way of example and not limitation, the selective attachment agent may adhere to the features of the pattern in a ratio ranging from 2:1 to 10:1, features to base layer.

In one or more embodiments, the selective attachment agent is a chemical functional group that may by further functionalized. Exemplary selective attachment agents include, but are not limited to, silanes, alkenes, alkynes, alcohols, silanols, amines, phosphines, phosphonic acids, and carboxylic acids. The specific selective attachment agent coated on the existing pattern may depend on the particular chemistry used in other components of method 200. For example, various phosphonic acids and esters are able to react selectively or at least preferentially with metal surfaces, either native or oxidized, to form strongly bound metal phosphonates preferentially or even selectively over surfaces of dielectric materials (e.g., oxides of silicon), and thus may be used as selective attachment agents coated on the features within the base layer. A specific example of a suitable phosphonic acid is octadecylphosphonic acid (ODPA). Such surface coatings generally tend to be stable in many organic solvents but may be removed using mild aqueous acid and base solutions. Phosphines (e.g., organophosphines) may also optionally be used. Other common acids such as sulfonic acids, sulfinic acids and carboxylic acids may also be optionally used.

Another example of a reaction that is selective or at least preferential to metal materials as compared to dielectric materials or organic polymeric materials or other materials, are various metal corrosion inhibitors, such as, for example those used during chemical mechanical polishing to protect interconnect structures. Specific examples include benzotriazole, other triazole functional groups, other suitable heterocyclic groups (e.g., heterocyclic based corrosion inhibitors), and other metal corrosion inhibitors known in the arts. In addition to triazole groups, other functional groups may be used to provide the desired attraction or reactivity toward the metals. Various metal chelating agents are also potentially suitable. Various amines (e.g., organoamines) are also potentially suitable.

Yet another example of a reaction that is selective or at least preferential to metal materials as compared to dielectric materials or organic polymeric materials or other materials, are various thiols. As another example, 1,2,4-triazole or similar aromatic heterocycle compounds may be used to react selectively with the metal as compared to dielectric and certain other materials. Selective attachment agents may also contain functional groups capable of reacting with a functional group of a polymer to bond the polymer to the surface. Various other metal poisoning compounds known in the arts may also potentially be used It is to be appreciated that these are just a few illustrative examples, and that still other examples will be apparent to those skilled in the arts and having the benefit of the present disclosure. The selective attachment agent may also include a polymer containing any of the aforementioned functional groups capable of selective attachment, where the polymer has functional groups along the main chain or as an end group and forms a layer of polymer chains attached to the target material.

In one or more embodiments, the selective attachment agent includes a solubility-shifting agent. The composition of the solubility-shifting agent may depend on the selective attachment agent. As will be appreciated by one of ordinary skill in the art, any suitable solubility-shifting agent may be included in the selective attachment agent provided that the two materials do not react with each other. Generally, the solubility-shifting agent may be any chemical that activates with light or heat. For example, in some embodiments, the solubility-shifting agent includes an acid or thermal acid generator (TAG). The acid or generated acid in the case of a TAG should be sufficient with heat to cause cleavage of the bonds of acid-decomposable groups of the polymer in a surface region of the first resist pattern to cause increased solubility of the first resist polymer in a specific developer to be applied. The acid or TAG is typically present in the composition in an amount of from about 0.01 to 20 wt % based on the total solids of the trimming composition.

Preferable acids are organic acids including non-aromatic acids and aromatic acids, each of which can optionally have fluorine substitution. Suitable organic acids include, for example: carboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid.

Exemplary aromatic acids that are free of fluorine include wherein aromatic acids of the general formula (I):

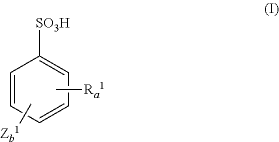

wherein: R1 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z1 independently represents a group chosen from carboxyl, hydroxy, nitro, cyano, C1 to C5 alkoxy, formyl and sulfonic acid; a and b are independently an integer from 0 to 5; and a+b is 5 or less.

Exemplary aromatic acids may be of the general formula (II):

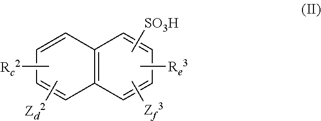

wherein: R2 and R3 each independently represents a substituted or unsubstituted C1-C20 alkyl group, a substituted or unsubstituted C5-C16 aryl group or a combination thereof, optionally containing one or more group chosen from carbonyl, carbonyloxy, sulfonamido, ether, thioether, a substituted or unsubstituted alkylene group, or a combination thereof; Z2 and Z3 each independently represents a group chosen from carboxyl, hydroxy, nitro, cyano, C1 to C5 alkoxy, formyl and sulfonic acid; c and d are independently an integer from 0 to 4; c+d is 4 or less; e and f are independently an integer from 0 to 3; and e+f is 3 or less.

Additional aromatic acids that may be included in the solubility-shifting agent include those the general formula (III) or (IV):

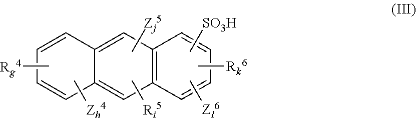

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 2; i+j is 2 or less; k and 1 are independently an integer from 0 to 3; and k+l is 3 or less;

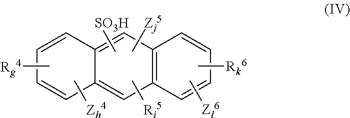

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 1; i+j is 1 or less; k and I are independently an integer from 0 to 4; and k+l is 4 or less.

Suitable aromatic acids may alternatively be of the general formula (V):

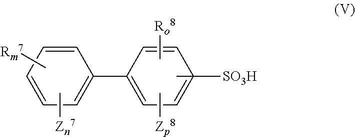

wherein: R7 and R8 each independently represents a substituted or unsubstituted C1-C20 alkyl group, a substituted or unsubstituted C5-C14 aryl group or a combination thereof, optionally containing one or more group chosen from carboxyl, carbonyl, carbonyloxy, sulfonamido, ether, thioether, a substituted or unsubstituted alkylene group, or a combination thereof; Z7 and Z8 each independently represents a group chosen from hydroxy, nitro, cyano, C1 to C5 alkoxy, formyl and sulfonic acid; m and n are independently an integer from 0 to 5; m+n is 5 or less; o and p are independently an integer from 0 to 4; and o+p is 4 or less.

Additionally, exemplary aromatic acids may have the general formula (VI):

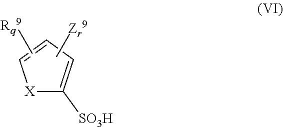

wherein: X is O or S; R9 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z9 independently represents a group chosen from carboxyl, hydroxy, nitro, cyano, C1 to C5 alkoxy, formyl and sulfonic acid; q and r are independently an integer from 0 to 3; and q+r is 3 or less.

In one or more embodiments, the acid is a free acid having fluorine substitution. Suitable free acids having fluorine substitution may be aromatic or nonaromatic. For example, free acid having fluorine substitution that may be used as solubility-shifting agent include, but are not limited to the following:

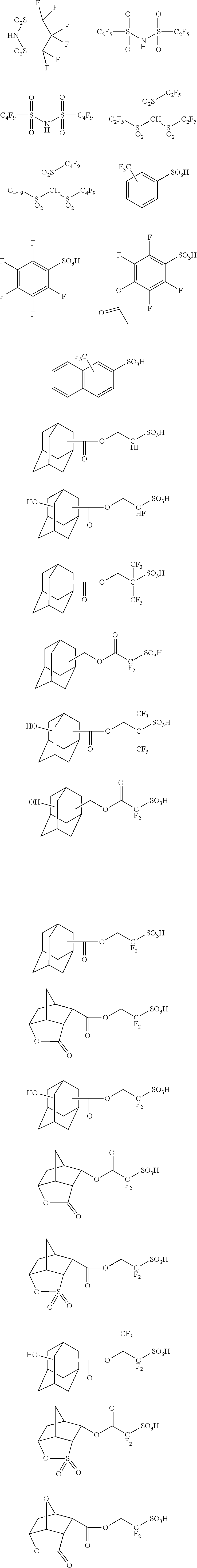

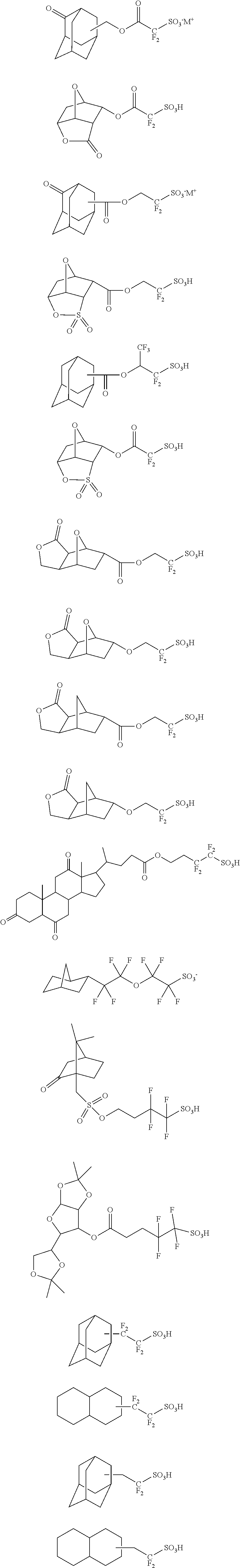

Suitable TAGs include those capable of generating a non-polymeric acid as described above. The TAG can be non-ionic or ionic. Suitable nonionic thermal acid generators include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof. Suitable ionic thermal acid generators include, for example, dodecylbenzenesulfonic acid triethylamine salts, dodecylbenzenedisulfonic acid triethylamine salts, p-toluene sulfonic acid-ammonium salts. p-toluene sulfonic acid-pyridinium salts, sulfonate salts, such as carbocyclic aryl and heteroaryl sulfonate salts, aliphatic sulfonate salts, and benzenesulfonate salts. Compounds that generate a sulfonic acid upon activation are generally suitable. Preferred thermal acid generators include p-toluenesulfonic acid ammonium salts, and heteroaryl sulfonate salts.

Preferably, the TAG is ionic with a reaction scheme for generation of a sulfonic acid as shown below:

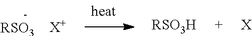

wherein RSO3⁻ is the TAG anion and X⁺ is the TAG cation, preferably an organic cation. The cation can be a nitrogen-containing cation of the general formula (I):

(BH) ⁺ (I)

which is the monoprotonated form of a nitrogen-containing base B. Suitable nitrogen-containing bases B include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B is preferably a heteroaromatic base.

Base B typically has a pKa from 0 to 5.0, or between 0 and 4.0, or between 0 and 3.0, or between 1.0 and 3.0. As used herein, the term “pKa” is used in accordance with its art-recognized meaning, that is, pKa is the negative log (to the base 10) of the dissociation constant of the conjugate acid (BH)+of the basic moiety (B) in aqueous solution at about room temperature. In certain embodiments, base B has a boiling point less than about 170° C., or less than about 160° C., 150° C., 140° C., 130° C., 120° C., 110° C., 100° C. or 90° C.

Exemplary suitable nitrogen-containing cations (BH)+include NH4⁺, CF2HNH2⁺, CF3CH2NH3⁺, (CH3)3NH⁺. (C2H5)3NH⁺, (CH3)2(C2H5)NH⁺ and the following:

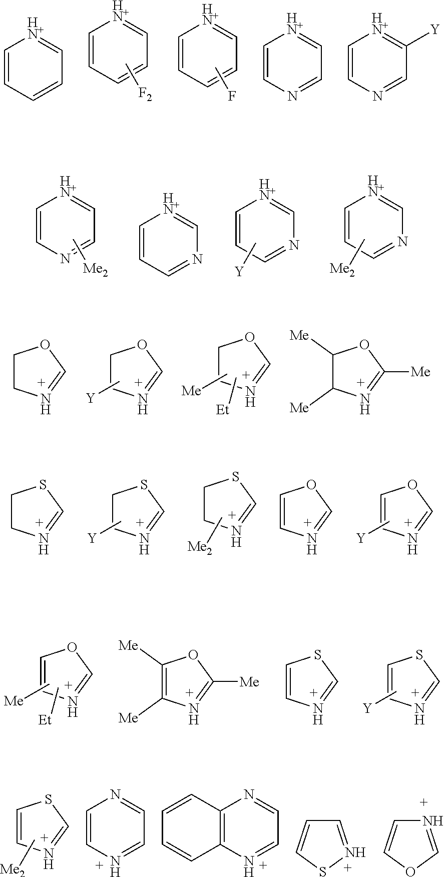

in which Y is alkyl, preferably, methyl or ethyl.

In particular embodiments, the solubility-shifting agents may be an acid such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; an acid generator such as triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; or a combination thereof.

Alternatively, the solubility-shifting agent may include a base or base generator. In such embodiments, suitable solubility-shifting agents include, but are not limited to, hydroxides, carboxylates, amines, imines, amides, and mixtures thereof. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines and heterocyclic amines. The amine may be a primary, secondary or tertiary amine. The amine may be a monoamine, diamine or polyamine. Suitable amines may include C1-30 organic amines, imines, or amides, or may be a C1-30 quaternary ammonium salt of a strong base (e.g., a hydroxide or alkoxide) or a weak base (e.g., a carboxylate). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-butyl 1,3-dihydroxy-2-(hydroxymethyl)propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate. In another embodiment, the amine is a hydroxyamine. Examples of hydroxyamines include hydroxyamines having one or more hydroxyalkyl groups each having 1 to about 8 carbon atoms, and preferably 1 to about 5 carbon atoms such as hydroxymethyl, hydroxyethyl and hydroxybutyl groups. Specific examples of hydroxyamines include mono-, di-and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol and triethanolamine.

Suitable base generators may be thermal base generators. A thermal base generator forms a base upon heating above a first temperature, typically about 140° C. or higher. The thermal base generator may include a functional group such as an amide, sulfonamide, imide, imine, O-acyl oxime, benzoyloxycarbonyl derivative, quarternary ammonium salt, nifedipine, carbamate, and combinations thereof. Exemplary thermal base generators include o-{(.beta.-(dimethylamino)ethyl)aminocarbonyl}benzoic acid, o-{(.gamma.-(dimethylamino)propyl)aminocarbonyl}benzoic acid, 2,5-bis{(.beta.-(dimethylamino)ethyl)aminocarbonyl}terephthalic acid, 2,5-bis{(.gamma.-(dimethylamino)propyl)aminocarbonyl}terephthalic acid, 2,4-bis{(.beta.-(dimethylamino)ethyl)aminocarbonyl}isophthalic acid, 2,4-bis{(.gamma.-(dimethylamino)propyl)aminocarbonyl}isophthalic acid, and combinations thereof.

Alternatively, in one or more embodiments, the solubility-shifting agent includes a crosslinker. Suitable crosslinkers that may be used as solubility-shifting agents include, but are not limited to, crosslinkers used for curing bis-epoxides such as bisphenol A diglycidyl ether, 2,5-bis[(2-oxiranylmethoxy)-methyl]-furan, 2,5-bis[(2-oxiranylmethoxy)methyl]-benzene, melamine, glycurils such as tetramethoxymethyl glycoluril and tetrabutoxymethyl glycoluril, benzoguanamine-based materials such as benzoguanamine, hydroxymethylbenzoguanamine, methylated hydroxymethylbenzoguanamine, ethylated hydroxymethylbenzoguanamine, and urea-based materials.

In one or more embodiments, the selective attachment agent includes a solvent. The solvent is typically chosen from water, organic solvents and mixtures thereof. In some embodiments, the solvent may include an organic-based solvent system comprising one or more organic solvents. The term “organic-based” means that the solvent system includes greater than 50 wt % organic solvent based on total solvents of the solubility-shifting agent composition, more typically greater than 90 wt %, greater than 95 wt %, greater than 99 wt % or 100 wt % organic solvents, based on total solvents of the solubility-shifting agent compositions. The solvent component is typically present in an amount of from 90 to 99 wt % based on the solubility-shifting agent composition.

Suitable organic solvents for the selective attachment agent composition include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C4-C9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C5-C9 fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and propylene glycol monomethyl ether; esters such as alkyl esters having a total carbon number of from 4 to 10, for example, propylene glycol monomethyl ether acetate, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate; ketones such as 2,5-dimethyl-4-hexanone and 2,6-dimethyl-4-heptanone; and polyethers such as dipropylene glycol monomethyl ether and tripropylene glycol monomethyl ether; and mixtures containing one or more of these solvents. In some embodiments, after coating the substrate with the selective attachment agent, the substrate is pretreated. The substrate may be pretreated to ensure attachment of the selective attachment agent to the surface of the features. The pretreatment may be a soft bake performed for about 30 to 90 seconds at a temperature ranging from 50 to 150° C.

After the selective attachment material is attached to the features, any excess material may be removed. As such, in one or more embodiments, after applying and optionally pretreating the selective attachment agent to the substrate, the substrate is rinsed to remove unused material.

Then, at block 206 of method 200, a first resist is deposited on the substrate. FIG. 3C shows a substrate coated with a selective attachment agent 303 and a first resist 304. The first resist may be a photoresist. Generally, a photoresist is a chemically amplified photosensitive composition that comprises a polymer, a photoacid generator, and a solvent. In one or more embodiments, the first resist includes a polymer. The polymer may be any standard polymer typically used in resist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the first resist. As will be appreciated by one having ordinary skill in the art, various protecting groups may be used for this reason. Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group which, on decomposition, forms a carboxylic acid on the polymer is preferably a tertiary ester group of the formula —C(O)OC(R¹)3 or an acetal group of the formula —C(O)OC(R²)2OR³, wherein: R¹ is each independently linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C1-6 alkyl, branched C3-6 alkyl, or monocyclic or polycyclic C3-10 cycloalkyl, each of which is substituted or unsubstituted, each R¹ optionally including
as part of its structure one or more groups chosen from —O—, —C(O)—, —C(O)—O—, or —S—, and any two R¹ groups together optionally forming a ring; R² is independently hydrogen, fluorine, linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably hydrogen, linear C1-6 alkyl, branched C3-6 alkyl, or monocyclic or polycyclic C3-10 cycloalkyl, each of which is substituted or unsubstituted, each R² optionally including as part of its structure one or more groups chosen from —O—,
—C(O)—, —C(O)—O—, or —S—, and the R² groups together optionally forming a ring; and R³ is linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C1-6 alkyl, branched C3-6 alkyl, or monocyclic or polycyclic C3-10 cycloalkyl, each of which is substituted or unsubstituted, R³ optionally including as part of its structure one or more groups chosen from —O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The polymer can further include as polymerized a monomer comprising an acid-labile group, the decomposition of which group forms an alcohol group or a fluoroalcohol group on the polymer. Suitable such groups include, for example, an acetal group of the formula —COC(R²)2OR³—, or a carbonate ester group of the formula —OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %. more typically from 30 to 70 mole %. based on total polymerized units of the polymer.

The photoacid generator is a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable photoacids include onium salts, for example, triphenylsulfonium trifhioromethanesulfonate, (p-tert-butoxyphenyl)diphenylsulfonium trifhioromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically comprise an anion having a sulfonate group or a non-sulfonate type group, such as a sulfonamidate group, a sulfonimidate group, a methide group, or a borate group.

The resist composition may optionally comprise a plurality of PAGs. The plural PAGs may be polymeric, non-polymeric, or may include both polymeric and non-polymeric PAGs. Preferably, each of the plurality of PAGs is non-polymeric. Preferably, when a plurality of PAGs are used, a first PAG comprises a sulfonate group on the anion and a second PAG comprises an anion that is free of sulfonate groups, such anion containing for example, a sulfonamidate group, a sulfonimidate group, a methide group, or a borate group such as described above. In some embodiments, the first resist has a composition similar to that of a positive tone developed (PTD) resist. In such embodiments, the first relief pattern may include a polymer made from the above described monomers, wherein any monomers including a reactive functional group are protected. As such, a PTD first resist may be organic soluble.

In other embodiments in which the solubility-shifting agent is a crosslinker, the first resist is a negative resist. In such embodiments, the first resist may include a polymer made from the above described monomers, wherein any monomers that comprise a reactive functional group are not protected. Suitable reactive functional groups include, but are not limited to, alcohols, carboxylic acids, and amines. Exposure to a crosslinker results in crosslinking of the polymer, rendering the polymer insoluble to developers. The uncrosslinked areas can then be removed using an appropriate developer.

In one or more embodiments, the first resist is a negative resist. In such embodiments, the first relief pattern may include a polymer made from the above described monomers, wherein any monomers including a reactive functional group are not protected. As such, the first resist may be soluble in either organic solvents or aqueous base. The tone of the resist (i.e., positive or negative) may influence the final pattern placement. For example, if the resist is similar to a PTD photoresist and the selective attachment agent contains an acid, the resist polymer above the feature will be deprotected and thus become soluble in aqueous base (e.g., TMAH), while the resist over the substrate will remain soluble in organic solvent. If the resist is similar to a negative photoresist and the selective attachment agent contains a crosslinker, the resist polymer above the feature will be crosslinked and insoluble while the resist over the substrate will remain soluble.

In one or more embodiments, the first resist is layered on the substrate such that it has a thickness of about 300 Å to about 3000 Å.

Then, at block 208 of method 200, the solubility-shifting agent is activated. In embodiments in which the solubility-shifting agent is an acid, acid generator, base, or base generator, activation of the solubility-shifting agent includes diffusing the solubility-shifting agent into the first resist to provide a solubility-shifted region of the first resist. The solubility-shifted region of the first resist may be dictated by the preferential adhesion of the selective attachment agent. For example, a selective attachment agent that preferentially adheres to the features of the existing pattern, as in selective patterning self-alignment such as method 200, may provide a solubility-shifted region of the first resist that is above the features. In one or more embodiments, the solubility-shifted region of the first resist extends vertically from the surface of the selective attachment agent coated on the feature to the surface of the first resist. In one or more embodiments, the solubility-shifted region extends in a sloped direction. When, the solubility-shifted region extends in a sloped direction, it may be desirable to prevent the features from merging together. To accomplish this, the feature thickness may be controlled to be sufficiently thin.

Diffusion of the solubility-shifting agent into the first resist is achieved by performing a bake. The bake may be carried out with a hotplate or oven. The temperature and time of the bake may depend on the identity of the second resist, and the desired amount of diffusion of the solubility-shifting agent into the second resist. Suitable conditions for the bake may include a temperature ranging from about 50° C. to about 160° C., and a time ranging from about 30 to about 90 seconds.

The solubility-shifted region of the first resist may be dictated by the preferential adhesion of the selective attachment agent. For example, when the selective attachment agent preferentially adheres to the features of the existing pattern, as in selective patterning self-alignment such as method 200, the solubility-shifted region of the first resist may be above the features. In one or more embodiments, the solubility-shifted region of the first resist may extend vertically to the surface of the first resist layer.

In embodiments in which the solubility-shifting agent is a crosslinker, activation of the solubility-shifting agent includes initiating polymerization of the crosslinker into the first resist. Activation of a crosslinker may provide a crosslinked region of the first resist. The crosslinked region of the first resist may be dictated by the preferential adhesion of the selective attachment agent. For example, when the selective attachment agent preferentially adheres to the features of the existing pattern, as in selective patterning self-alignment, the crosslinked region of the first resist may be above the features.

Finally, at block 210 of method 200, the first resist is developed using a first developer. The first developer may be any developer commonly used in the art. The composition of the first developer may depend on the solubility characteristic of the first resist. For example, if the first resist is a positive tone developed resist, the specific developer may be a base such as tetramethylammonium hydroxide. On the other hand, if the first resist is a negative tone developed resist, the specific developer may be a nonpolar organic solvent, such as n-butyl acetate or 2-heptanone. In one or more embodiments, the solubility-shifted or crosslinked region is insoluble in the first developer. Accordingly, after developing the first resist, the solubility-shifted or crosslinked region of the first resist may remain on the substrate. As such, method 200 may provide a substrate, as shown in FIG. 3D, that includes a pattern of the solubility-shifted first resist 305, where the solubility-shifted first resist is directly on top of the features 302 of the existing pattern.

Alternatively, in one or more embodiments, the solubility-shifted region becomes is soluble in the first developer. In such embodiments, after developing the first resist, the solubility-shifted region of the first resist is removed from the substrate. A coated substrate in accordance with such embodiments is shown in FIG. 3E. In FIG. 3E, a substrate includes a pattern of the first resist 306 that is offset from the features 302 which are coated in the selective attachment agent 303. Such pattern may be referred to as an anti-selective pattern as the features of the resist remain above the base layer, which was not coated with the selective attachment agent.

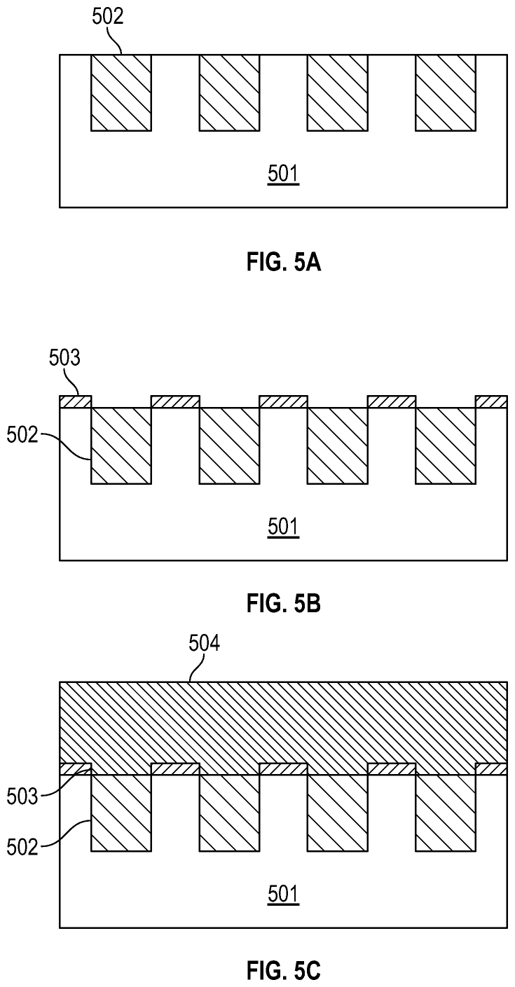

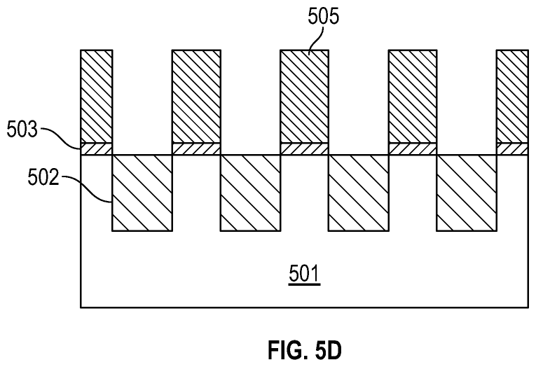

As noted above, in one or more embodiments, methods include selectively forming a pattern of resist alternate to the features within the base layer. Such methods, like method 200, may be considered selective pattern formation as they form a pattern of first relief according to the placement of the selective attachment agent. However, methods that selectively form a pattern or first relief alternate to the existing pattern of features may be referred to as selective anti-alignment, as the two patterns do not align. A method, 400, of selective anti-alignment pattern formation (e.g., the pattern shown in FIG. 1B) in accordance with the present disclosure is shown in, and discussed with reference to, FIG. 4. Schematic depictions of a coated substrate at various points during the method are shown in FIGS. 5A-D.

In method 400, an existing pattern is provided on a substrate at block 402. A coated substrate with an existing pattern is shown in FIG. 5A. In FIG. 5A, the existing pattern may include features 502 within a base layer 501. The features and the base layer are as previously described with reference to method 200.

Then, at block 404 of method 400, the substrate is coated with a selective

attachment agent. In one or more embodiments, the selective attachment agent is coated on the entire substrate expect for the target region (i.e., the selective attachment agent is coated over the entire base layer, except for the features). As described above, the selective attachment agent may preferentially adhere to one material of the existing pattern. In one or more embodiments, in method 400, the selective attachment agent adheres to the base layer of the existing pattern. FIG. 5B shows a substrate including a selective attachment agent 503 coating the first layer rather than the features of the existing pattern. The selective attachment agent may adhere to the features of the pattern in a ratio great than 1:1. By way of example and not limitation, the selective attachment agent may adhere to the base layer of the existing pattern in a ratio ranging from 1:2 to 1:10, features to base layer.

In one or more embodiments, the selective attachment agent is a chemical functional group that may by further functionalized. Exemplary selective attachment agents that are selective for dielectric materials over metals include, but are not limited to, silanes and alcohols. The specific selective attachment agent coated on the existing pattern may depend on the particular chemistry used in other components of method 200. For example, aminosilanes, halosilanes (e.g., chlorosilanes, fluorosilanes, etc.), and alkoxysilanes (e.g., methoxysilanes, ethoxysilanes, and other alkoxysilanes) are able to react selectively or at least preferentially with hydroxylated groups on the surface of the dielectric material as compared to the metal material. Specific examples of suitable silanes include, but are not limited to, trichlorooctadecylsilane, octadecylchlorosilane, diethylaminotrimethyl silanes, bis(dimethylamino)dimethylsilane, methoxysilanes, ethoxysilanes, and other similar silanes, and combinations thereof. Reaction products of these reactions may be used to selectively cover the exposed surface of the dielectric material. If a certain generally lesser amount of reaction does occur on the metal material it may be removed, for example, by a wash with water. The silanes may include one or more other groups, such as, for example, straight alkane chains, branched alkane chains, other straight or branched organic chains, benzylic groups, or other organic groups, or various other known functional groups, in order to alter the chemical properties of the silanes and achieve the desired chemical properties. Compounds containing hydroxy groups, such as alcohols and catechols, are also known to react with hydroxylated groups of a dielectric material. As another example, bi-functional, tri-functional, multi-functional electrophiles, or a combination thereof, may be reacted with hydroxylated groups of a material (e.g., an ILD) followed by reaction with functional group of a polymer with the resulting activated reaction product. The selective attachment agent may also include a polymer containing any of the aforementioned functional groups capable of selective attachment, where the polymer has functional groups along the main chain or as an end group and forms a layer of polymer chains attached to the target material. $Various other selective attach agents known in the arts may also potentially be used. It is to be appreciated that these are just a few illustrative examples, and that still other examples will be apparent to those skilled in the arts and having the benefit of the present disclosure.

In one or more embodiments, the selective attachment agent includes a solubility-shifting agent. The solubility-shifting agent may a solubility-shifting agent as previously described with reference to method 200.

In some embodiments, after coating the substrate with the selective attachment agent, the substrate is pretreated. The pretreatment may be a bake performed for about 30 to 90 minutes at 50 to 150° C.

In method 400, at block 406, a first resist is deposited on the substrate. A substrate coated with a first resist 504 is shown in FIG. 5C. In one or more embodiments, the first resist is as previously described with reference to method 200. In one or more embodiments, the first resist is layered on the substrate such that it has a thickness of about 300 Å to about 3000 Å.

At block 408 of method 400, the solubility-shifting agent is activated. In embodiments in which the solubility-shifting agent is an acid, acid generator, base, or base generator, activation of the solubility-shifting agent includes diffusing the solubility-shifting agent into the first resist to provide a solubility-shifted region of the first resist, as described above.

The solubility-shifted region of the first resist may be dictated by the preferential adhesion of the selective attachment agent. For example, when the selective attachment agent preferentially adheres to the base layer of the existing pattern, as in anti-selective pattern self-alignment, e.g., method 400, the solubility-shifted region of the first resist may be above the base layer. In one or more embodiments, the solubility-shifted region of the first resist may extend vertically to the surface of the first resist layer.

In embodiments in which the solubility-shifting agent is a crosslinker, activation of the solubility-shifting agent includes initiating polymerization of the crosslinker into the first resist. Activation of a crosslinker may provide a crosslinked region of the first resist. The crosslinked region of the first resist may be dictated by the preferential adhesion of the selective attachment agent. For example, when the selective attachment agent preferentially adheres to the base layer of the existing pattern, as in anti-selective pattern self-alignment, the crosslinked region of the first resist may be above the base layer. The crosslinked region of the first resist may extend vertically from the base layer to the surface of the first resist.

Finally, in method 400, the first resist is developed at block 410. The first resist may be developed using a first developer. The first developer may be chosen based on the solubility characteristics of the first resist. In one or more embodiments, the solubility-shifted or crosslinked region of the first resist is insoluble in the first developer. Accordingly, after developing the first resist, the solubility-shifted or crosslinked region of the first resist may remain on the substrate. As such, method 400 may provide a substrate, as shown in FIG. 5D, that includes a pattern of the solubility-shifted first resist 505, where the solubility-shifted first resist is offset from the features 502 of the existing pattern.

In one or more embodiments, an anti-selective pattern self-alignment process may be altered such that the solubility-shifted region is soluble in the first developer. In such alternate embodiments, after development, the remaining modified first resist is positioned on top of the features of the existing pattern, such as in selective pattern self-alignment.

Similarly, in one or more embodiments, a selective pattern self-alignment process may be altered such that the solubility-shifted region is soluble in the first developer. In such alternate embodiments, after development, the remaining modified first resist is offset from the features of the existing pattern, such as in anti-selective pattern self-alignment.

In one or more embodiments, methods disclosed herein may be used in double patterning features over/next to an existing pattern. Such methods may implement two selective pattern self-alignment process, two anti-selective pattern self-alignment process, or one selective pattern self-alignment process and one anti-selective pattern self-alignment process to achieve double patterning.

In an alternative embodiment, the features are coated with a first selective attachment agent that contains a first solubility-shifting agent, and the base layer is coated with a second selective attachment agent that contains a second solubility-shifting agent. In some embodiments, the first solubility-shifting agent comprises an acid or acid generator and the second solubility-shifting agent comprises a base or base generator. The resist is then deposited on the substrate and the solubility-shifting agents are simultaneously activated. The first solubility-shifting agent diffuses from the top of the features and the second solubility-shifting agent from the top of the base layer. At the interface of the diffusion front, the solubility-shifting agents can interact with each other to prevent switching of solubility of the resist in lateral areas outside a vertical plane perpendicular to the substrate and located at the interface of the features and the exposed base layer. This helps constrain the switching of solubility to areas of the resist that are above the features, thereby limiting lateral growth of the openings and creating an approximately straight edge rather than a sloped profile.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

1. A method of microfabrication comprising:
providing a substrate having an existing pattern, wherein the existing pattern comprises features formed within a base layer such that a top surface of the substrate has the features uncovered and the base layer is uncovered;
depositing a selective attachment agent on the substrate, wherein the selective attachment agent comprises a solubility-shifting agent;
depositing a first resist on the substrate;
activating the solubility-shifting agent such that a portion of the first resist becomes insoluble to a first developer; and
developing the first resist using the first developer such that the portion of the first resist insoluble to the first developer remains.

2. The method of claim 1, wherein the selective attachment agent adheres to surfaces of the features more than to surfaces of the base layer.

3. The method of claim 1, wherein the selective attachment agent comprises a phosphonic acid, phosphonate ester, a phosphine, a sulfonic acid, a sulfinic acid, a carboxylic acid, a triazole, a thiol, or a combination thereof.

4. The method of claim 1, wherein the portion of the first resist that becomes insoluble to the first developer is above the features.

5. The method of claim 1, wherein the selective attachment agent adheres to surfaces of the base layer more than surfaces of the features.

6. The method of claim 1, wherein the selective attachment agent comprises a silane, an alcohol, or a combination thereof.

7. The method of claim 1, wherein the portion of the first resist that becomes insoluble to the first developer is above the base layer.

8. The method of claim 1, wherein the solubility-shifting agent comprises an acid generator.

9. The method of claim 8, wherein the acid generator is free of fluorine.

10. The method of claim 8, wherein the acid generator is selected from the group consisting of triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, and combinations thereof.

11. The method of claim 1, wherein the solubility-shifting agent comprises an acid.

12. The method of claim 11, wherein the acid is free of fluorine.

13. The method of claim 11, wherein the acid is selected from the group consisting of trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, and combinations thereof.

14. The method of claim 1, further comprising, prior to depositing the first resist on the substrate, pre-treating the substrate.

15. A method of microfabrication, the method comprising:
providing a substrate having an existing pattern, wherein the existing pattern comprises features formed within a base layer such that a top surface of the substrate has the features uncovered and the base layer is uncovered;
depositing a selective attachment agent on the substrate, wherein the selective attachment agent comprises a solubility-shifting agent;
depositing a first resist on the substrate;
activating the solubility-shifting agent such that a portion of the first resist becomes soluble to a first developer; and
developing the first resist using the first developer such that the portion of the first resist soluble to the first developer are removed.

16. The method of claim 15, wherein the selective attachment agent adheres to surfaces of the features more than to surfaces of the base layer.

17. The method of claim 15, wherein the portion of the first resist that becomes insoluble to the first developer is above the features.

18. The method of claim 15, wherein the selective attachment agent comprises a phosphonic acid, phosphonate ester, a phosphine, a sulfonic acid, a sulfinic acid, a carboxylic acid, a triazole, a thiol, or a combination thereof.

19. (canceled)

20. (canceled)

21. (canceled)

22. (canceled)

23. (canceled)

24. (canceled)

25. (canceled)

26. A method of microfabrication comprising:
providing a substrate having an existing pattern, wherein the existing pattern comprises features formed within a base layer such that a top surface of the substrate has the features uncovered and the base layer s uncovered;
depositing a first selective attachment agent on the substrate, wherein the first selective attachment agent comprises a first solubility-shifting agent, and wherein the first selective attachment agent adheres to surfaces of the features more than to surfaces of the base layer;
depositing a second selective attachment agent on the substrate, wherein the second selective attachment agent comprises a second solubility-shifting agent, and wherein the second selective attachment agent adheres to surfaces of the base layer more than to surfaces of the features;
depositing a first resist on the substrate;
activating the first and second solubility-shifting agents such that a portion of the first resist becomes insoluble to a first developer; and
developing the first resist using the first developer such that the portion of the first resist insoluble to the first developer remains.

27. The method of claim 26, wherein the first solubility-shifting agent comprises an acid or acid generator and the second solubility-shifting agent comprises a base or base generator.
